(19) United States
(12) Patent Application Publication
(10) Pub. No.: US 2007/0229105 A1
(43) Pub. Date: Oct. 4, 2007

(54) Desktop wafer analysis station

(75) Inventor: Morgan T. Johnson, Portland, OR (US)

Correspondence Address: RAYMOND J. WERNER, 2056 NW ALOCLEK DRIVE, SUITE 314, HILLSBORO, OR, 97124, US

(73) Assignee: Octavian Scientific, Inc.

(21) Appl. No.: 11/729,039

(22) Filed: Mar. 27, 2007

Related U.S. Application Data
(60) Provisional application No. 60/786,928, filed on Mar. 28, 2006.

(51) Int. Cl. G01R 31/02

(52) U.S. Cl. 324/758

(57) ABSTRACT

A small-footprint wafer analysis, or test, station, suitable for personal or desktop use, includes a chuck mounted upon a base, an x-y motion mechanism slidably attached to the base, a contact array carrier slidably attached to the x-y motion mechanism, and an optical alignment mechanism attached to the contact array carrier.

### CROSS-REFERENCE TO RELATED APPLICATIONS

This non-provisional application claims the benefit of earlier filed provisional application 60/786,928, filed 28 Mar. 2006, and entitled “Desktop Wafer Analysis Station”; the entirety of which is hereby incorporated by reference.

### FIELD OF THE INVENTION

The present invention relates generally to semiconductor test equipment, and more particularly relates to a low-cost, small-footprint, wafer analysis, or test, station.

### BACKGROUND

Advances in semiconductor manufacturing technology have resulted in, among other things, reducing the cost of sophisticated electronics to the extent that integrated circuits have become ubiquitous in the modern environment.

As is well-known, integrated circuits are typically manufactured in batches, and these batches usually contain a plurality of semiconductor wafers within and upon which integrated circuits are formed through a variety of semiconductor manufacturing steps, including, for example, depositing, masking, patterning, implanting, etching, and so on.

Completed wafers are tested to determine which die, or integrated circuits, on the wafer are capable of operating according to predetermined specifications. In this way, integrated circuits that cannot perform as desired are not packaged, or otherwise incorporated into finished products.

In the course of developing test programs, or analyzing integrated circuits for the purposes of debugging or yield improvement, it is often necessary for personnel to engage in these engineering tasks in a production test environment. This is undesirable in that it interferes with production, and in that the engineers or technicians are not at their desks or labs where it is more convenient for them to work.

What is needed are low-cost, small-footprint, methods and apparatus for electrically communicating with one or more integrated circuits on a wafer.

### BRIEF DESCRIPTION OF THE DRAWINGS

FIG. 1 shows a semiconductor wafer, and a wafer translator prior to attachment to the wafer.

FIG. 2 shows a wafer with a wafer translator attached thereto, which assembly may be referred to as a translated wafer.

FIG. 3 shows a wafer analysis station, and a translated wafer prior to being disposed upon the chuck of the wafer analysis station, and further shows an illustrative x-y motion mechanism having a contact array carrier slidably attached to the x-y motion mechanism, and an optical alignment means further attached to the contact array carrier.

FIG. 4 is similar to FIG. 3, but shows the x-y motion mechanism at the end of its travel in one direction, and further shows the translated wafer being removed from the chuck.

FIG. 5 is similar to FIG. 4, but shows the translated wafer disposed on the chuck prior to being removed.

FIG. 6 is similar to FIG. 5, but further shows alternative arrangements for implementation of the contact array carrier.

### SUMMARY OF THE INVENTION

Briefly, a small-footprint wafer analysis, or test, station, suitable for personal or desktop use, includes a chuck mounted upon a base, an x-y motion mechanism slidably attached to the base, a contact array carrier slidably attached to the x-y motion mechanism, and an optical alignment mechanism attached to the contact array carrier.

### DETAILED DESCRIPTION

Reference herein to “one embodiment”, “an embodiment”, or similar formulations, means that a particular feature, structure, operation, or characteristic described in connection with the embodiment, is included in at least one embodiment of the present invention. Thus, the appearances of such phrases or formulations herein are not necessarily all referring to the same embodiment. Furthermore, various particular features, structures, operations, or characteristics may be combined in any suitable manner in one or more embodiments.

### Terminology

Reference herein to “circuit boards”, unless otherwise noted, is intended to include any type of substrate upon which circuits may be placed. For example, such substrates may be rigid or flexible, ceramic, flex, epoxy, FR4, or any other suitable material.

The terms chip, integrated circuit, semiconductor device, and microelectronic device are sometimes used interchangeably in this field. The present invention relates to the manufacture and test of chips, integrated circuits, semiconductor devices, microelectronic devices, and similar items.

Pad refers to a metallized region of the surface of an integrated circuit, which is used to form a physical connection terminal for communicating signals to and/or from the integrated circuit.

The expression “wafer translator” refers to an apparatus facilitating the connection of pads (sometimes referred to as terminals, I/O pads, contact pads, bond pads, bonding pads, chip pads, test pads, or similar formulations) of unsingulated integrated circuits, to other electrical components, devices, or equipment. It will be appreciated that “I/O pads” is a general term, and that the present invention is not limited with regard to whether a particular pad of an integrated circuit is part of an input, output, or input/output circuit. A wafer translator is typically disposed between a wafer and other electrical components, and/or electrical connection pathways. The wafer translator is typically removably attached to the wafer (alternatively the wafer is removably attached to the translator). The wafer translator includes a substrate having two major surfaces, each surface having terminals disposed thereon, and electrical pathways disposed through the substrate to provide for electrical continuity between at least one terminal on a first surface and at least one terminal on a second surface. The wafer-side of the wafer translator has a pattern of terminals that matches the layout of at least a portion of the pads of the integrated circuits on the wafer. The wafer translator, when disposed between a wafer and other electrical components, makes electrical contact with one or more pads of a plurality of integrated circuits on the wafer, providing an electrical pathway therethrough to the other electrical components. The wafer translator is a structure that is used to achieve electrical connection between one or more electrical terminals that have been fabricated at a first scale, or dimension, and a corresponding set of electrical terminals that have been fabricated at a second scale, or dimension. The wafer translator provides an electrical bridge between the smallest features in one technology (e.g., pins of a probe card) and the largest features in another technology (e.g., bonding pads of an integrated circuit). For convenience, wafer translator is referred to simply as translator where there is no ambiguity as to its intended meaning. In some embodiments a flexible wafer translator offers compliance to the surface of a wafer mounted on a rigid support, while in other embodiments, a wafer offers compliance to a rigid wafer translator. The surface of the translator that is configured to face the wafer in operation is referred to as the wafer-side of the translator. The surface of the translator that is configured to face away from the wafer is referred to as the inquiry-side of the translator. An alternative expression for inquiry-side is tester-side.

Inquiry system refers to devices or equipment, the intended function of which may include, but is not limited to, providing power, and/or signals to one or more integrated circuits on a wafer, and/or receiving one or more signals from one or more integrated circuits on a wafer. One example of an inquiry system is semiconductor test system.

Inquiry system interface refers to apparatus disposed between the inquiry side of a translator and an inquiry system. Inquiry system interfaces provide at least electrical pathways coupled between coupled between the inquiry side of a translator and an inquiry system. Inquiry system interfaces may incorporate a variety of passive and/or active electrical components, as well as a variety of mechanical devices for attaching, coupling, connecting, or communicating to the inquiry side of a translator and/or the inquiry system (e.g., a tester). Various implementations of inquiry system interfaces may be as simple as a circuit board that passes signals from one surface to the other, or may be complex apparatus including active electronics, and mechanical devices suitable for placing, orienting and/or aligning the inquiry system interface.

The expression “edge extended wafer translator” refers to an embodiment of a translator in which electrical pathways disposed in and/or on the translator lead from terminals, which in use contact the wafer under test, to electrical terminals disposed outside of a circumferential edge of a wafer aligned for connection with, or attached to the edge extended translator.

The expression “translated wafer” refers to a wafer/wafer translator pair that are in the attached state, wherein a predetermined portion of, or all of, the contact pads of the integrated circuits on the wafer are in electrical contact with corresponding electrical connection means disposed on the wafer-side of the translator. Removable attachment may be achieved, for example, by means of vacuum, or pressure differential, attachment.

Advanced inquiry transport refers to a wafer/wafer translator pair in the attached state (i.e., a translated wafer) that are further provided with a lip seal mechanism and a support ring, or suitable alternative support structure, such that the translated wafer may maintain attachment (typically vacuum attachment) and be easily transported from one inquiry system to another, wherein each of these inquiry systems is equipped with an inquiry system interface.

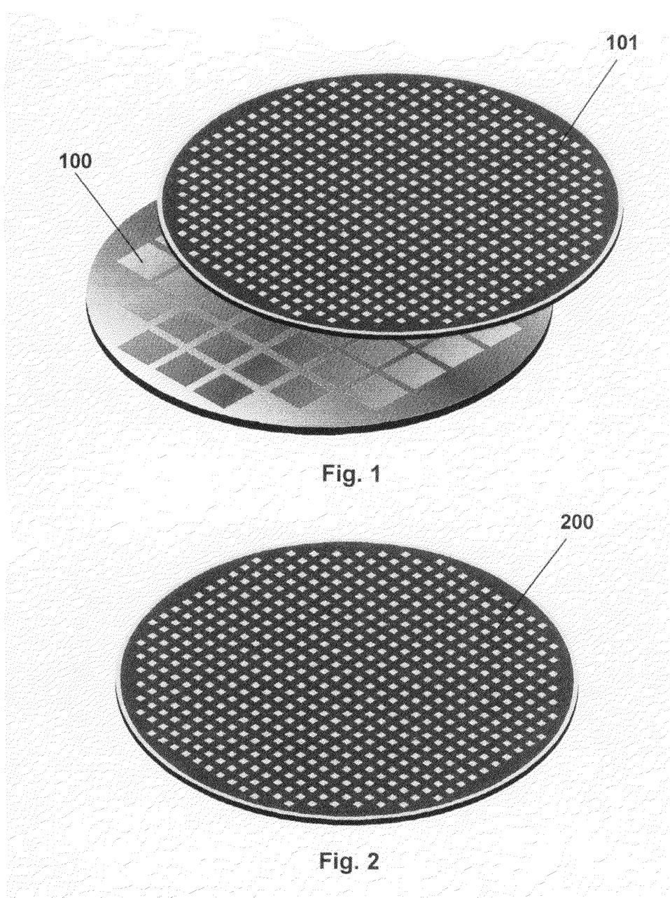

FIG. 1 shows a semiconductor wafer 100, and a wafer translator 101 prior to wafer 100 and wafer translator 101 being brought into the attached state. Wafer 100 is not limited to any particular size, thickness, or semiconductor manufacturing process. Wafer translator 101, includes a first and a second major surface, and provides on the first surface thereof, a plurality of electrical contacts that are arranged in a pattern such that when the first side of wafer translator 101 is brought into contact with wafer 100, electrical connections are formed between those electrical contacts and at least a portion of the pads, of the integrated circuits on wafer 100. Wafer translator 101 further provides an insulating body with electrical pathways therethrough which provide for electrical connection between the plurality of electrical contacts of the first surface of wafer translator 101 with a corresponding plurality of electrical contact pads disposed on the second surface of wafer translator 101. It is noted that the electrical contact pads on the second surface of wafer translator 101 are typically larger than the electrical contacts on the first surface of wafer translator 101. Additionally, the electrical contact pads on the second surface of wafer translator 101 are typically arranged in a regular, repeating pattern.

FIG. 2 shows a wafer/wafer translator pair in the attached state 200 (i.e., wafer 100 with wafer translator 101 attached thereto). As noted above, the wafer/wafer translator pair in the attached state 200 may be referred to as a translated wafer. The attached state of the wafer/wafer translator pair is typically temporary rather than permanent, and is typically achieved by means of drawing a vacuum between the wafer and the wafer translator with a gasket, or similar sealing means, disposed therebetween.

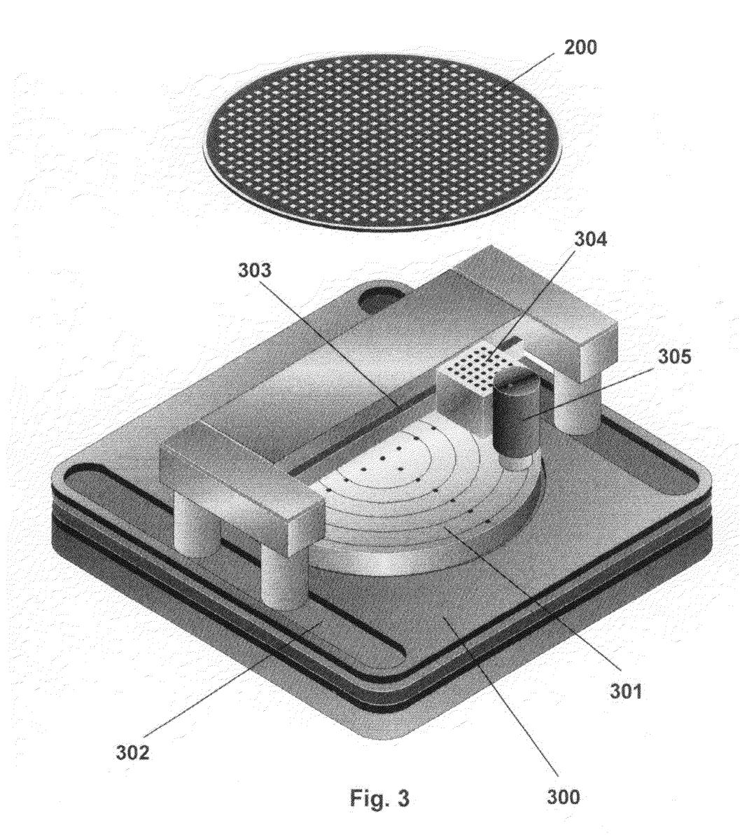

FIG. 3 shows a desktop wafer analysis station 300, and a translated wafer 200 prior to being disposed upon a chuck 301 of desktop wafer analysis station 300, and further shows an illustrative x-y motion mechanism 303 having a contact array carrier 304 slidably attached to x-y motion mechanism 303, and an optical alignment means 305 further attached to contact array carrier 304. As can be seen in the figures, contact array carrier 304 has a first surface that faces the inquiry-side of the translated wafer, and a second, opposite side, for providing access to an inquiry system such as a tester. The first side of contact array carrier 304 may be referred to as the inquiry-side, and the second side may be referred to as the inquiry-system-side. Electrical continuity between contact structures on the first side and contact structures on the second of contact array carrier 304 is provided through the body of contact array carrier 304. Contact array carrier 304 includes contact structures on its first surface that are suitable for making electrical contact with contact pads on the inquiry-side of the wafer translator, and further includes contact pads or terminals suitable for providing electrical communication to an inquiry system interface. A variety of structures are suitable for use in making electrical contact between the first side of contact array carrier 304 and the inquiry-side of the wafer translator, including, but not limited to, pogo pins, fixed pins, and contact pads. A similar variety of structures may be used on the second surface of contact array carrier 304.

In an alternative embodiment, the inquiry-side of the wafer translator may be provided with electrically conductive pins extending outwardly from the inquiry-side of the wafer translator in a substantially perpendicular manner. In this alternative arrangement, the first side of contact array carrier 304 is provided with an interface suitable for making connection with those pins. For example, the first side of contact array carrier 304 may be provided with a zero-insertion-force (ZIF) socket interface.

In the illustrative embodiment, wafer analysis station 300 has a base portion with a pair of parallel grooves, or channels in which x-y motion mechanism 303 may slidably move along a first axis. It is noted that motion in the x and/or y directions may be achieved by a variety of means including, but not limited to, motorized action and/or hand-cranked action. Such motorized action may be controlled by computer with an interface to accept user commands specifying the x-y location at which contact array carrier 304 is to be positioned. Specifics of computer control of motors for positioning an item is well-understood and therefore is not further described herein.

Still referring to FIG. 3, contact array carrier 304 is slidably attached to x-y motion mechanism 303, and this slidable attachment is adapted to provide motion in a second axis, where the second axis is orthogonal to the first axis. Contact array carrier 304 may be adapted to move in the z-axis such that contact is made with the underlying translated wafer 200.

In alternative embodiments, chuck 301 may rise up in the z-axis so that the inquiry-side of translated wafer 200 makes contact with contact array carrier 304. It is noted that motion of chuck 301 in the z-axis may be driven by a motor, or hand-cranked. It is further noted that rotational motion of chuck 301 may be driven by a motor or hand-cranked. It will be appreciated that rotational motion of chuck 301 facilitates alignment of the inquiry-side of the wafer translator to contact array carrier 304. It is further noted that chuck 301 provides vacuum hold-down of the translated wafer 200. In various embodiments, chuck 301 is a heated chuck, i.e., it may actively provide heating the wafer of the wafer/wafer translator pair.

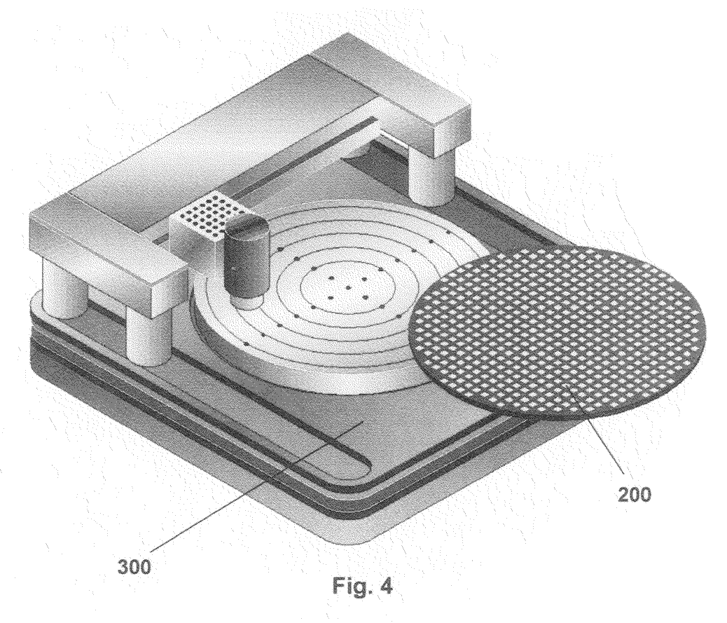

FIG. 4 is similar to FIG. 3, but shows x-y motion mechanism 303 at the end of its travel in one direction, and further shows translated wafer 200 being removed from chuck 301.

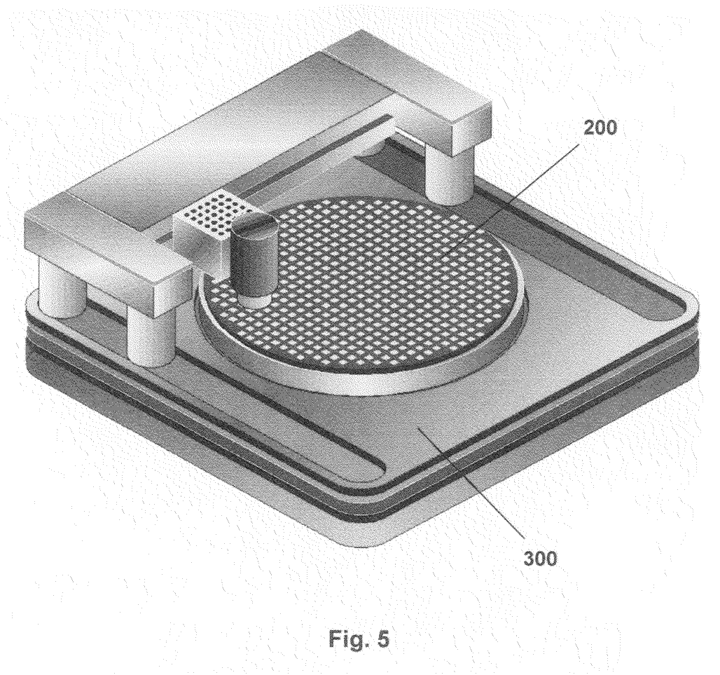

FIG. 5 is similar to FIG. 4, but shows translated wafer 200 disposed on chuck 301 prior to being removed.

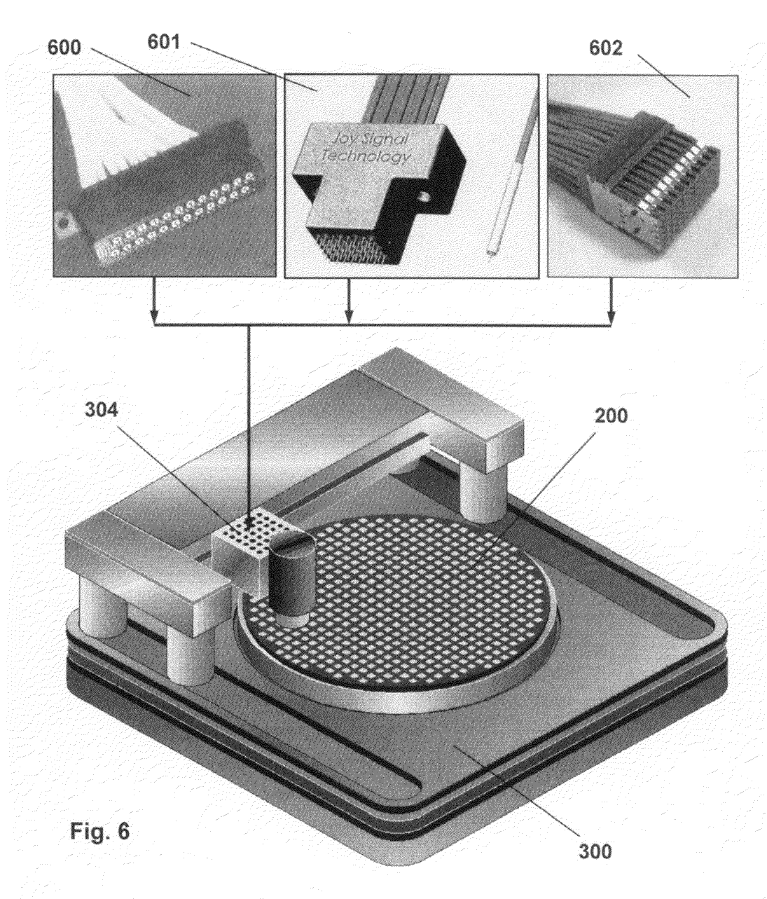

FIG. 6 is similar to FIG. 5, but further shows various connector arrangements 600, 601, 602, for implementation of contact array carrier 304. It is noted that the wiring shown in connector arrangements 600, 601, 602, provides the electrical pathway to/from the inquiry system.

Once translated wafer 200 is disposed on chuck 301 of desktop wafer analysis station 300, contact array carrier 304 may be aligned to the electrical contact pads on the inquiry-side of wafer translator 101 through the use of optical alignment means 305. Optical alignment means 305 may be a simple magnifier and cross-hair arrangement through which a user looks while maneuvering x-y motion mechanism 303 and contact array carrier 304 until it is aligned with the desired set of electrical contact pads. Contact array carrier 304 may then be brought into electrical contact with the electrical contact pads of the inquiry-side of wafer translator 101. It is noted that optical alignment means 305 may alternatively be implemented as an automated vision system which finds one or more marks present on the inquiry-side of wafer translator 101, and then navigates to the desired location over translated wafer 200.

In an alternative embodiment, the x-y step, or pitch, needed to move from one set of inquiry-side contacts to another (representing electrical access to a first integrated circuit and then another) are provided to a computer-based controller that operates motors for positioning contact array carrier 304. In this way, a user may instruct the computer based controller to provide access to a particular set of inquiry-side contacts. It will be appreciated that a set of inquiry-side contacts accessed by contact array carrier 304 may provide access to less than all the pads of a single integrated circuit, all the pads of an integrated circuit, or some or all of the pads of two or more integrated circuits.

Contact array carrier 304 provides at least part of the electrical pathway between translated wafer 200 and an inquiry system (not shown). Such an inquiry system may provide power and signals to the device under test, and may further receive signals from the device under test.

In various alternative embodiments, chuck 301 may include vacuum hold-down means; the base may be made of any suitable material or combination of materials; the base may be implemented as a unitary body or may be assembled from component pieces; and the chuck may be removable so that it can be replaced by another of a different size, or with different capabilities, such as heating and cooling capabilities.

It will be appreciated that a wafer test station in accordance with the present invention does not require the high degree of alignment precision that would otherwise be necessary to make electrical connection with the very small contact, or bonding, pads of the integrated circuits on the wafer, because wafer translator 101 provides electrical connection to the device or devices under test while presenting much larger electrical contacts on its inquiry-side to make contact with contact array carrier 304.

In an alternative embodiment of the present invention, desktop wafer analysis station 300 has a chuck that is adapted to receive an advanced inquiry transport assembly, rather than simply a translated wafer. In other words, the translated wafer with lip seal and support ring are placed onto a desktop wafer analysis station which is sized to accommodate the lip seal and support ring, and then the inquiry-side of the wafer translator and the first side of the contact array carrier are brought into contact.

In a further alternative embodiment, desktop wafer analysis station 300 provides a path for an active vacuum line that is attachable to the wafer translator of a wafer/wafer translator pair. Such an active vacuum line may be used to maintain the vacuum between the wafer and the wafer translator.

### Conclusion

The exemplary methods and apparatus described herein find application in the field of integrated circuit test and analysis, particularly when such integrated circuits are in wafer form.

An advantage of some embodiments of the present invention is that access to unsingulated integrated circuits may be had without sophisticated alignment means because electrical contact is made to the contact structures on the inquiry-side of wafer translator rather than to the much smaller pads of the integrated circuits themselves.

Another advantage of some embodiments of the present invention is that users may electrically access various integrated circuits on the wafer many times non-sequentially without having to make a corresponding number of touchdowns on those integrated circuits with probe needles. The present invention allows repeated non-sequential electrical access without causing pad damage that conventionally occurs when probing unsingulated integrated circuits. Such damage is typically caused by the scrubbing action of conventional probe needles.

It is noted that embodiments of the present invention are not limited to use on a desktop. Rather this nomenclature is intended to convey the practicality and relatively small dimensions of wafer analysis stations in accordance with the present invention.

It is to be understood that the present invention is not limited to the embodiments described above, but encompasses any and all embodiments within the scope of the subjoined Claims and their equivalents.

What is claimed is:

1. A method of providing electrical access to one or more unsingulated integrated circuits on a wafer, comprising:
providing the wafer having a front-side and a back-side;
providing a wafer translator having a wafer-side and an inquiry-side;
removably attaching the front-side of the wafer and the wafer-side of the wafer translator to produce a wafer/wafer translator pair;
disposing the wafer/wafer translator pair upon a chuck such that the back-side of the wafer is in contact with the chuck; and
aligning a first contact structure layout on the inquiry-side of the contact array carrier to the inquiry-side of the wafer translator;
wherein the contact array carrier is slidably attached to an x-y motion mechanism, the x-y motion mechanism is mounted to a base, and the chuck is movably mounted to the base.

2. The method of claim 1, further comprising moving the chuck in the z-direction such that a selected set of contact structures on the inquiry-side of the wafer translator are in electrical contact with a set of contact structures on the inquiry-side of the contact array carrier.

3. The method of claim 1, wherein removably attaching comprises vacuum attaching.

4. The method of claim 1, wherein aligning includes receiving an optical image of the inquiry-side of the wafer translator subsequent to disposition upon the chuck.

5. The method of claim 4, wherein aligning further comprises rotating the chuck.

6. The method of claim 2, wherein further comprising:
moving the chuck in the z-direction away from the contact array carrier;
moving the chuck in the z-direction so as to re-make contact with the contact array carrier:
wherein re-making contact with the contact array carrier excludes scrubbing the pads of the unsingulated integrated circuits on the wafer.

7. The method of claim 1, further comprising heating at least a portion of the chuck.

8. The method of claim 1, further comprising providing a lip seal around the outer circumference of the wafer/wafer translator pair.

9. The method of claim 2, electrically connecting an inquiry system to a second contact structure layout on the inquiry-system-side of the contact array carrier.

10. The method of claim 9, providing electrical signals to one or more integrated circuits on the wafer through the contact array carrier.

11. The method of claim 1, further comprising providing active vacuum to the wafer/wafer translator pair.

12. The method of claim 1, further comprising providing an x-y step required to move the contact array carrier from a first set of inquiry-side side contacts of the wafer translator to a second set of inquiry-side contacts of the wafer translator.

13. The method of claim 12, wherein the x-y step is provided to a computer-based controller that is operable to control one or more motors connected to position the contact array carrier.

14. A method of providing electrical access to one or more unsingulated integrated circuits on a wafer, comprising:
providing the wafer having a front-side and a back-side;
providing a wafer translator having a wafer-side and an inquiry-side;
removably vacuum attaching the front-side of the wafer and the wafer-side of the wafer translator to produce a wafer/wafer translator pair;
combining the wafer/wafer translator pair with a lip seal and support ring to form an advanced inquiry transport assembly;
disposing the advanced inquiry transport assembly upon a chuck such that the back-side of the wafer is in contact with the chuck; and
aligning a first contact structure layout on the inquiry-side of the contact array carrier to the inquiry-side of the advanced inquiry transport assembly;
wherein the contact array carrier is slidably attached to an x-y motion mechanism, the x-y motion mechanism is mounted to a base, and the chuck is movably mounted to the base.

15. The method of claim 15, further comprising moving the chuck in the z-direction such that a selected set of contact structures on the inquiry-side of the wafer translator of the advanced inquiry transport assembly are in electrical contact with a set of contact structures on the inquiry-side of the contact array carrier.
